(19) United States
(12) Patent Application Publication
(10) Pub. No.: US 2012/0069487 A1
(43) Pub. Date: Mar. 22, 2012

(54) STACKED STRUCTURE AND METHOD OF MANUFACTURING THE SAME

(75) Inventors: Hitoshi Noguchi, Kobe-shi (JP); Naoki Tanaka, Neyagawa-shi (JP); Tatsuya Nakamura, Osaka-shi (JP)

(73) Assignee: SANYO ELECTRIC CO., LTD., Moriguchi-shi, Osaka (JP)

(21) Appl. No.: 13/375,159

(22) PCT Filed: May 7, 2010
(86) PCT No.: PCT/JP2010/057817

§ 371 Date: Nov. 29, 2011

(30) Foreign Application Priority Data
May 29, 2009 (JP) 2009-130015

(51) Int. Cl. H01G 4/08; C23C 14/34; C23C 16/44; B05D 5/12; B05D 1/12

(52) U.S. Cl. 361/301.4; 427/79; 204/192.1

(57) ABSTRACT

[Problem to be Solved]

A problem to be solved is to provide a stacked structure and a method of manufacturing the same that make generation of insulation breakdown unlikely, while providing a high dielectric constant and a high quality.

[Means for Solving Problem]

A stacked structure according to the present invention is a stacked structure in which a dielectric layer 3 is provided between a first conductive layer 1 and a second conductive layer 2. The dielectric layer 3 includes a dielectric film 31 formed on the first conductive layer 1, and a dielectric particle film 32 formed by applying a dispersion solution containing dielectric particles onto the dielectric film 31. A method of manufacturing the stacked structure according to the present invention includes a dielectric layer forming step of forming the dielectric layer 3 on the first conductive layer 1, and a conductive layer forming step of forming the second conductive layer 2 on the dielectric layer 3. The dielectric layer forming step includes a dielectric film forming step of forming the dielectric film 31 on the first conductive layer 1, and a particle film forming step of forming the dielectric particle film 32 by applying a dispersion solution containing dielectric particles onto the dielectric film 31.

### TECHNICAL FIELD

The present invention relates to a stacked structure such as a circuit board in which a capacitor circuit is formed, and a capacitor element, and a method of manufacturing the stacked structure.

### BACKGROUND ART

A stacked structure of this types is formed by providing a dielectric layer between a first conductive layer and a second conductive layer. The dielectric layer is formed on a surface of the first conductive layer by using various known film deposition processes such as sol-gel process, MOCVD (metal organic chemical vapor deposition) process, and sputtering deposition process (see patent literature 1, for example).

However, in the aforementioned film deposition processes, a pinhole or a crack is easily generated in the dielectric layer. So, if the second conductive layer is formed directly on the dielectric layer by using sputtering deposition process or plating process, part of metal constituting the second conductive layer may penetrate into the pinhole or the crack. This causes a fear of generation of breakdown of insulation between the first and second conductive layers through the pinhole or the crack.

Meanwhile, tiny projections and depressions exist on a surface of the first conductive layer. So, making the dielectric film thinner results in a fear of generation of exposure of part of the first conductive layer at a surface of the dielectric film. As a result, the exposed part of the first conductive layer may contact the second conductive layer if the second conductive layer is formed directly on the dielectric layer, causing a fear of generation of breakdown of insulation between the first and second conductive layers.

Provision of a resin film between the dielectric layer and the second conductive film has been suggested in order to solve the aforementioned problem (see patent literature 1).

### CITATION LIST

### Patent Literature

Patent literature 1: Japanese Patent Publication No. 3841814

### SUMMARY OF INVENTION

### Problems to be Solved by the Invention

However, the aforementioned structure with the resin film provided between the dielectric layer and the second conductive film suffers from a problem of reduction of the dielectric constant or quality of the stacked structure. Further, a difference in coefficient of expansion between the dielectric layer and the resin film may generate a failure such as a crack in the stacked structure, leading to a problem of quality reduction.

It is therefore an object of the present invention to provide a stacked structure and a method of manufacturing the same that make generation of insulation breakdown unlikely, while providing a high dielectric constant and a high quality.

### Means for Solving Problems

A stacked structure according to the present invention is a stacked structure in which a dielectric layer is provided between a first conductive layer and a second conductive layer. The dielectric layer includes a dielectric film formed on the first conductive layer, and a dielectric particle film formed by applying a dispersion solution containing dielectric particles onto the dielectric film.

The stacked structure includes stacked structures of various types such as a circuit board with a capacitor circuit formed by providing a dielectric layer between a first conductive layer and a second conductive layer and formed on a substrate, a capacitor element, and a stacked sheet from which a capacitor element can be cut out.

In the aforementioned stacked structure, a pinhole or a crack is generated easily in the dielectric film. So, if the second conductive layer is formed directly on the dielectric film by using sputtering deposition process, plating process, screen printing process or the like, part of metal constituting the second conductive layer may penetrate into the pinhole or the crack. This causes a fear of generation of breakdown of insulation between the first and second conductive layers through the pinhole or the crack.

In addition, tiny projections and depressions exist on a surface of the first conductive layer. So, making the dielectric film thinner results in a fear of generation of exposure of part of the first conductive layer at a surface of the dielectric film. As a result, the exposed part of the first conductive layer may contact the second conductive layer if the second conductive layer is formed directly on the dielectric film, causing a fear of generation of breakdown of insulation between the first and second conductive layers.

In response, in the stacked structure according to the present invention, the dielectric particle film is formed by applying a dispersion solution containing dielectric particles onto the dielectric film. So, even if a pinhole or a crack exists in the dielectric film, the dispersion solution penetrates into the pinhole or the crack. Thus, the pinhole or the crack is filled with part of the dielectric particle film. In addition, even if part of the first conductive layer is exposed at the surface of the dielectric film, the exposed part is covered with the dielectric particle film.

Thus, insulation between the first and second conductive layers is maintained by the dielectric particle film.

If a pinhole or a crack is generated in the dielectric film as described above, the dielectric constant of the stacked structure is reduced due to the effect of a gap generated by the pinhole or the crack. In the stacked structure according to the present invention, however, the pinhole or the crack is filled with part of the dielectric particle film, thereby suppressing reduction of the dielectric constant.

In a specific formation of the aforementioned stacked structure, the dielectric particles are made of a material having the same main component as that of a dielectric material constituting the dielectric film.

This specific formation makes a difference in coefficient of thermal expansion between the dielectric film and the dielectric particle film smaller, thereby suppressing an internal defect to be generated by thermal expansion. As a result, the quality of the stacked structure is maintained at a high level.

In a different specific formation of the aforementioned stacked structure, the dielectric particles contain at least one of the following materials as a main component including barium titanate, lithium niobate, lithium borate, lead zirconate titanate, strontium titanate, lead lanthanum zirconate titanate, lithium tantalite, zinc oxide, and tantalum oxide. These dielectric particles may contain an additive intended to enhance dielectric properties.

In a still different specific formation of the aforementioned stacked structure, the dielectric film is formed by one of the following processes including sol-gel process, MOCVD process, sputtering deposition process, and powder spraying coating process.

Powder spraying coating process includes various film deposition processes such as aerosol deposition process and powder jet deposition process by which dielectric powder is sprayed to form a dielectric film.

A method of manufacturing a stacked structure according to the present invention is a method of manufacturing a stacked structure in which a dielectric layer is provided between a first conductive layer and a second conductive layer. The method includes a dielectric layer forming step of forming the dielectric layer on the first conductive layer, and a conductive layer forming step of forming the second conductive layer on the dielectric layer.

Here, the dielectric layer forming step includes a dielectric film forming step of forming a dielectric film on the first conductive layer, and a particle film forming step of forming a dielectric particle film by applying a dispersion solution containing dielectric particles onto the dielectric film.

In a specific formation of the aforementioned manufacturing method, the dispersion solution used in the particle film forming step contains dielectric particles that are made of a material having the same main component as that of a dielectric material constituting the dielectric film.

In a different specific formation of the aforementioned manufacturing method, the dielectric film is formed in the dielectric film forming step by using one of the following processes including sol-gel process, MOCVD process, sputtering deposition process, and powder spraying coating process.

Powder spraying coating process includes various film deposition processes such as aerosol deposition process and powder jet deposition process by which dielectric powder is sprayed to form a dielectric film.

### Effect of the Invention

The stacked structure according to the present invention makes generation of insulation breakdown unlikely, while providing a high dielectric constant and a high quality. Further, the manufacturing method according to the present invention is capable of manufacturing a stacked structure that makes generation of insulation breakdown unlikely, while providing a high dielectric constant and a high quality.

### BRIEF DESCRIPTION OF DRAWINGS

FIG. 1 is a sectional view showing a circuit board of an embodiment according to the present invention.

FIG. 2 is a sectional view used to explain a dielectric film forming step that is one of steps of manufacturing the circuit board.

FIG. 3 is a sectional view used to explain a particle film forming step that is one of the steps of manufacturing the circuit board.

FIG. 4 is a view showing a film deposition unit used in aerosol deposition process.

FIG. 5 is a sectional view showing a spraying unit used in powder jet deposition process.

### EMBODIMENTS FOR CARRYING OUT INVENTION

In an embodiment described in detail below by referring to drawings, the present invention is carried out in a circuit board in which a capacitor circuit is formed.

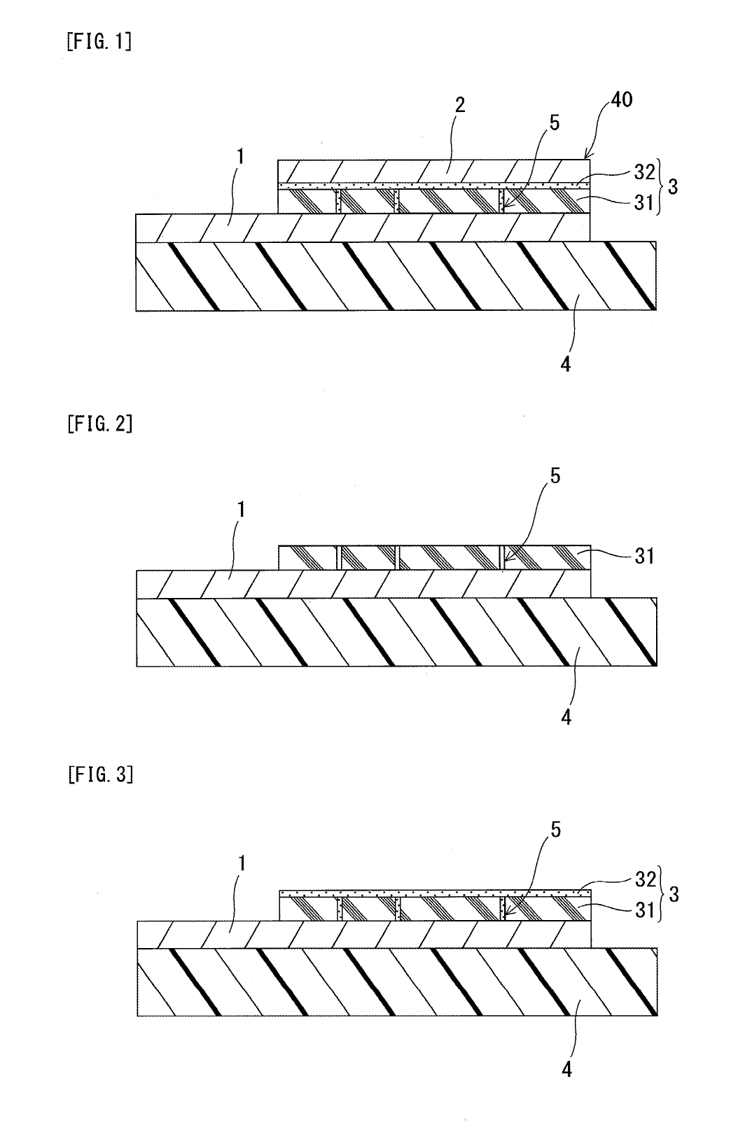

As shown in FIG. 1, the circuit board according to the embodiment of the present invention is a stacked structure with a capacitor circuit (40) formed by providing a dielectric layer (3) between a first conductive layer (1) and a second conductive layer (2), and a substrate (4) on which the capacitor circuit (40) is formed. The first conductive layer (1) is metallic foil provided on the first substrate (4), and is made of metal such as copper (Cu), nickel (Ni), cobalt (Co), gold (Au), and platinum (Pt). The first conductive layer (1) may be formed by using sputtering deposition process, plating process, screen printing process, or the like.

The dielectric layer (3) is composed of a dielectric film (31) formed on the first conductive layer (1), and a dielectric particle film (32) formed on the dielectric film (31).

The dielectric film (31) is made of a dielectric material mainly containing barium titanate (BaTiO3). Further, the thickness of the dielectric film (31) is about 0.5 μm. However, 0.5 μm is not the only thickness of the dielectric film (31), but the dielectric film (31) may have a greater or smaller thickness.

The dielectric particle film (32) is formed by applying a dispersion solution with dielectric particles mainly containing barium titanate (BaTiO3) onto the dielectric film (31). The dielectric particles in the dispersion solution are nanoparticles having an average particle diameter of 50 nm or smaller. The dielectric particle film (32) is a thin film formed by flocculation of the dielectric particles as a result of drying of the dispersion solution applied on the dielectric film (31).

In the present embodiment, the same material mainly containing barium titanate (BaTiO3) is used as the dielectric film (31) and the dielectric particles constituting the dielectric particle film (32). However, the present invention is not intended to be limited to this, but the present invention may use various dielectric materials mainly containing lithium niobate (LiNbO3), lithium borate (Li2B4O7), lead zirconate titanate (PbZrTiO3), strontium titanate (SrTiO3), lead lanthanum zirconate titanate (PbLaZrTiO3), lithium tantalite (LiTaO3), zinc oxide (ZnO), and tantalum oxide (Ta2O5). Dielectric materials having different main components may be used as the dielectric film (31) and the dielectric particles constituting the dielectric particle film (32).

The dielectric film (31) and the dielectric particles constituting the dielectric particle film (32) may contain an additive intended to enhance dielectric properties.

The second conductive layer (2) is a metal film formed on the dielectric layer (3) by using sputtering deposition process, plating process, screen printing process, or the like. Or, the second conductive layer (2) is metallic foil provided on the dielectric layer (3). Like the first conductive layer (1), the second conductive layer (2) is made of metal such as copper (Cu), nickel (Ni), cobalt (Co), gold (Au), and platinum (Pt).

A method of manufacturing the aforementioned circuit board is descried next. In this manufacturing method, a dielectric layer forming step of forming the dielectric layer (3) on the first conductive layer (1), and a conductive layer forming step of forming the second conductive layer (2) on the dielectric layer (3), are performed in this order.

Further, the dielectric layer forming step includes a dielectric film forming step of forming the dielectric film (31) on the first conductive layer (1) as shown in FIG. 2, and a particle film forming step of forming the dielectric particle film (32) on the dielectric film (3) as shown in FIG. 3.

In the dielectric film forming step, any one of sol-gel process, MOCVD process, sputtering deposition process, and powder spraying coating process is employed to form the dielectric film (31) on the first conductive layer (1). Powder spraying coating process includes various film deposition processes such as aerosol deposition process and powder jet deposition process by which dielectric powder is sprayed to form a dielectric film.

Sol-gel process is a known film deposition process of forming a dielectric film at a low temperature ranging between room temperature and a temperature of about 150° C. MOCVD and sputtering deposition processes are known film deposition processes of forming a dielectric film in vacuum.

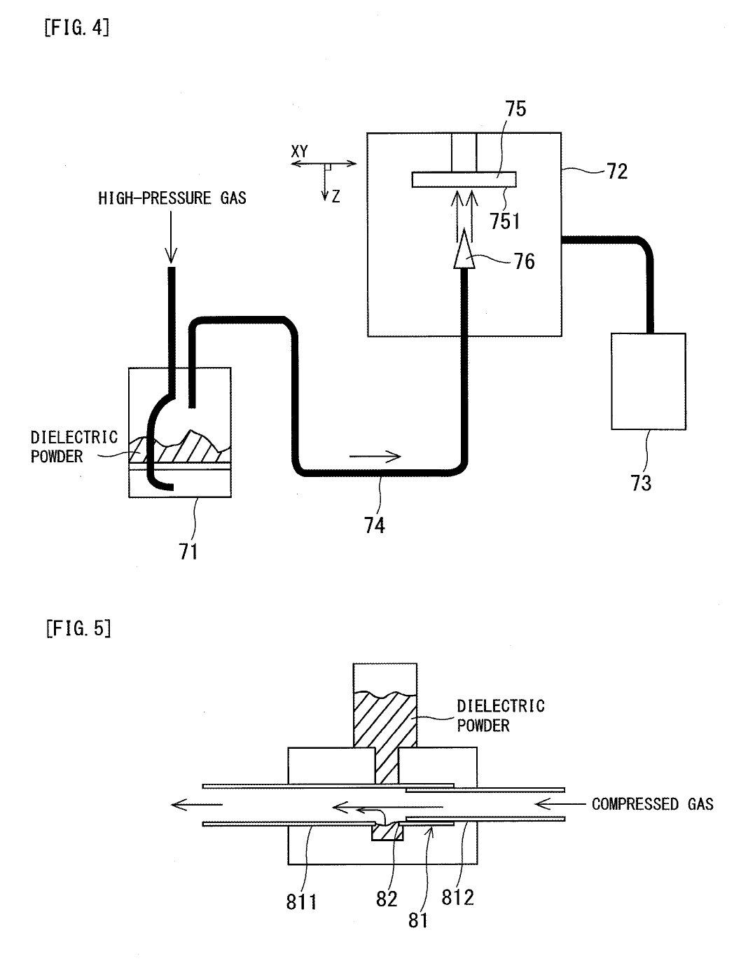

Aerosol deposition process is a film deposition process performed by using a film deposition unit shown in FIG. 4 and in which dielectric powder is formed into an aerosol, and the powder is sprayed onto a surface on which a dielectric film is to be formed, thereby forming the dielectric film.

As shown in FIG. 4, the film deposition unit has a structure where an aerosol generator (71) in which dielectric powder is agitated and mixed with high-pressure gas to be formed into an aerosol, and a film deposition chamber (72) capable of keeping the vacuum state inside with a vacuum pump (73), are connected through a narrow transfer tube (74). The inside of the film deposition chamber (72) is kept in vacuum during film deposition. So, a difference in pressure is generated between space inside the aerosol generator (71) into which the high-pressure gas flows (high-pressure space), and space inside the film deposition chamber (72) (low-pressure space). As a result, the dielectric powder formed into an aerosol in the aerosol generator (71) is caused to flow toward the film deposition chamber (72) through the transfer tube (74).

A stage (75) to hold a target object with a surface on which a dielectric film is to be formed is placed inside the film deposition chamber (72). The stage (75) has a structure that allows translational movement in XY plane parallel to a placement surface (751) on which the target object is placed, translational movement in the direction of Z axis perpendicular to the XY plane, and rotation about the Z axis.

One end of the transfer tube (74) is placed in the film deposition chamber (72). A nozzle (76) in the form of a slit is attached to this end such that a tip end thereof is pointed toward the placement surface (751) of the stage (75). Further, the nozzle (76) has such a shape that allows the speed of discharge of the dielectric powder through one end of the transfer tube (74) to be increased to about 100 m/sec.

Thus, the dielectric powder discharged at a high speed through the tip end of the nozzle (76) is sprayed onto the surface of the target object on the stage (75).

Powder jet deposition process is a film deposition process performed by using a spraying unit shown in FIG. 5 and in which dielectric powder is sprayed onto a surface on which a dielectric film is to be formed, thereby forming the dielectric film.

As shown in FIG. 5, the spraying unit includes a stepped nozzle (81) with two regions (811) and (812) of different inner diameters. The nozzle (81) is provided with a through hole (82) formed in the first region (811) of a large inner diameter and at a position near the second region (812) of a smaller inner diameter, and through which dielectric powder is supplied.

So, if compressed gas is caused to flow in the nozzle (81) from the second region (812) toward the first region (811), a negative pressure is generated at a position near an outlet of the second region (812) at which the inner diameter changes. This negative pressure sucks dielectric powder into the nozzle (81), so the dielectric powder sucked in is discharged at a high speed trough a tip end of the nozzle (81) together with the compressed gas.

Like in aerosol deposition process, the discharged dielectric powder is sprayed onto a surface of a target object placed on a stage.

In the present embodiment, for formation of the dielectric film (31) on the first conductive layer (1) by using aerosol deposition process or powder jet deposition process, dielectric powder of barium titanate (BaTiO3) having a particle diameter of about 1 μm is sprayed onto a surface of the first conductive layer (1).

The dielectric powder sprayed on the surface of the first conductive layer (1) collides with the surface of the first conductive layer (1) or with different dielectric powder to be pulverized, and is then deposited on the first conductive layer (1). As a result, the dielectric film (31) is formed on the first conductive layer (1). So, the dielectric film (31) becomes a film in the form of a dense bulk if it is formed by aerosol deposition process or powder jet deposition process.

In the particle film forming step, a dispersion solution with dielectric particles mainly containing barium titanate (BaTiO3) is applied onto the dielectric film (31) formed in the dielectric film forming step, and is dried, thereby forming the dielectric particle film (32). The dispersion solution used in the particle film forming step contains nanoparticles as dielectric particles having an average particle diameter of 50 nm or smaller. It is preferable that the dispersion solution be a solution in which these nanoparticles are monodispersed as primary particles.

As a result, the dielectric film (31) formed in the dielectric film forming step, and the dielectric particle film (32) formed in the particle film forming step, constitute the dielectric layer (3).

In the conductive layer forming step, a metal film is provided by using sputtering deposition process, plating process, screen printing process, or the like on the dielectric particle film (32) formed in the particle film forming step, or metallic foil is provided on the dielectric particle film (32), thereby forming the second conductive layer (2). As a result, formation of the circuit board with the substrate (4) and the capacitor circuit (40) formed on the substrate (4) is completed as shown in FIG. 1.

If metallic foil is used as the second conductive layer (2), the metallic foil may be provided above a surface of the dielectric film (31) coated with the dispersion solution after the dispersion solution is applied in the particle film forming step and before the dispersion solution is dried. This makes the dielectric particle film (32) to be provided between the dielectric film (31) and the metallic foil function as an adhesive layer for making adhesive contact between the dielectric film (31) and the metallic foil.

In the circuit board manufactured in the aforementioned manner, pinholes (5) shown in FIG. 2 or a crack is generated easily in the dielectric film (31). So, if the second conductive layer (2) is formed directly on the dielectric film (31) by using sputtering deposition process, plating process, screen printing process or the like, part of the metal constituting the second conductive layer (2) may penetrate into the pinholes (5) or the crack. This causes a fear of generation of breakdown of insulation between the first conductive layer (1) and the second conductive layer (2) through the pinholes (5) or the crack.

In addition, tiny projections and depressions exist on a surface of the first conductive layer (1). So, making the dielectric film (31) thinner results in a fear of generation of exposure of part of the first conductive layer (1) at a surface of the dielectric film (31). As a result, the exposed part of the first conductive layer (1) may contact the second conductive layer (2) if the second conductive layer (2) is formed directly on the dielectric film (31), causing a fear of generation of breakdown of insulation between the first conductive layer (1) and the second conductive layer (2).

In response, in the circuit board according to the present embodiment, the dielectric particle film (32) is formed by applying a dispersion solution containing dielectric particles onto the dielectric film (31). So, even if the pinholes (5) or a crack exists in the dielectric film (31), the dispersion solution penetrates into the pinholes (5) or the crack. Thus, the pinholes (5) or the crack is filled with part of the dielectric particle film (32). In addition, even if part of the first conductive layer (1) is exposed at the surface of the dielectric film (31), the exposed part is covered with the dielectric particle film (32).

Thus, insulation between the first conductive layer (1) and the second conductive layer (2) is maintained by the dielectric particle film (32).

If the pinholes (5) or a crack is generated in the dielectric film (31) as described above, the dielectric constant of the capacitor circuit of the circuit board is reduced due to the effect of a gap generated by the pinholes (5) or the crack. In the circuit board according to the present embodiment, however, the pinholes (5) or the crack is filled with part of the dielectric particle film (32), thereby suppressing reduction of the dielectric constant.

Also, in the circuit board according to the present embodiment, the dielectric particle film (32) is made of a material having the same main component as that of the dielectric material constituting the dielectric film (31). This makes a difference in coefficient of thermal expansion between the dielectric film (31) and the dielectric particle film (32) smaller, thereby suppressing an internal defect to be generated by thermal expansion. As a result, the quality of the circuit board is maintained at a high level.

The structure of each part of the present invention is not limited to that shown in the embodiment described above. Various modifications can be devised without departing from the technical scope recited in claims. By way of example, the aforementioned elements employed in a circuit board in which a capacitor circuit is formed are also applicable in a capacitor element, or a stacked sheet from which a capacitor element can be cut out. The capacitor element and the stacked sheet may not have an element corresponding to the substrate (4) as part of the aforementioned circuit board.

### REFERENCE SIGNS LIST

(1) First conductive layer
(2) Second conductive layer
(3) Dielectric layer
(31) Dielectric film
(32) Dielectric particle film
(4) Substrate
(5) Pinhole

1. A stacked structure comprising:
a first conductive layer;
a dielectric film formed on the first conductive layer;
a dielectric particle film formed by applying a dispersion solution containing dielectric particles onto the dielectric film; and
a second conductive layer formed on the dielectric particle film.

2. The stacked structure according to claim 1, wherein the dielectric particles are made of a material having the same main component as that of a dielectric material constituting the dielectric film.

3. The stacked structure according to claim 1, wherein the dielectric particles contain at least one of the following materials as a main component including barium titanate, lithium niobate, lithium borate, lead zirconate titanate, strontium titanate, lead lanthanum zirconate titanate, lithium tantalite, zinc oxide, and tantalum oxide.

4. The stacked structure according to claim 1, wherein the dielectric film is formed by one of the following processes including sol-gel process, MOCVD process, sputtering deposition process, and powder spraying coating process.

5. A method of manufacturing a stacked structure in which a dielectric layer is provided between a first conductive layer and a second conductive layer, the method comprising the steps of:
(a) forming a dielectric film on the first conductive layer;
(b) forming a dielectric particle film by applying a dispersion solution containing dielectric particles onto the dielectric film; and
(c) forming the second conductive layer on the dielectric particle film.

6. The method of manufacturing a stacked structure according to claim 5, wherein the dispersion solution used in the step (b) contains dielectric particles that are made of a material having the same main component as that of a dielectric material constituting the dielectric film.

7. The method of manufacturing a stacked structure according to claim 5, wherein the dielectric film is formed in the step (a) by using one of the following processes including sol-gel process, MOCVD process, sputtering deposition process, and powder spraying coating process.
